(19) United States
(12) Patent Application Publication
(10) Pub. No.: US 2001/0023125 A1
(43) Pub. Date: Sep. 20, 2001

(54) INTERLAYER INSULATING FILM FORMING METHOD, SEMICONDUCTOR DEVICE AND METHOD OF MANUFACTURING THE SAME

(76) Inventors: YUHKO NISHIMOTO, TOKYO (JP); KAZUO MAEDA, TOKYO (JP)

Correspondence Address: LORUSSO & LOUD, 3137 MT VERNON AVENUE, ALEXANDRIA, VA, 22305

(21) Appl. No.: 08/897,839

(22) Filed: Jul. 21, 1997

(30) Foreign Application Priority Data
Dec. 25, 1996 (JP) 8-346351

(51) Int. Cl. H01L 21/4763

(52) U.S. Cl. 438/623

(57) ABSTRACT

There is disclosed a method of forming stress-adjusted insulating films which are interposed between respective interconnection layers upon laminating metal interconnection layers in excess of three-layer. Multiple layers whose total stress is adjusted are formed by laminating insulating films 22a to 22e, 23a to 23d on a substrate 21.

### BACKGROUND OF THE INVENTION

1. Field of the Invention

The present invention relates to a stress-adjusted insulating film forming method, a semiconductor device and a method of manufacturing the same and, more particularly, a method of forming stress-adjusted insulating films which are interposed between respective metal interconnection layers upon laminating three or more metal interconnection layers, a semiconductor device employing the stress-adjusted insulating films and a method of manufacturing the same.

2. Description of the Prior Art

In recent years, a multilayered interconnection structure in excess of three-layer has been needed with the progress of high integration density of the semiconductor device. Upper and lower interconnections and adjacent interconnections are insulated with the interlayer insulating films interposed therebetween. However, in such multilayered interconnection structure in excess of three-layer, it is extremely important to bury narrow interconnection regions with leaving no void therein and also to planarize surfaces of such buried interconnection regions.

In the meanwhile, as for various kinds of insulating films, their characteristics have been known for one skilled in the art, as indicated in Table I below.

TABLE I

| Type of | Step | | Film |
|---|---|---|---|
| insulating film | coverage | Flatness | quality |
| SOG film | ∘ | ∘ | x |
| TEOS/O₃ thermal | ⊚ | ∘ | ∘ |
| CVD film | | | |
| Plasma CVD film | x | x | ∘ |
| High density | | | |
| plasma CVD film | ⊚ | x | ∘ |

As one of the interlayer insulating films to be formed between multilayered interconnections in excess of three-layer, a combination of plural insulating films consisting of an insulating film with good film quality and an insulating film with good step coverage may be employed. For instance, a combination of the plasma CVD film and the TEOS/O₃thermal CVD film or SOG film is often recommended. In other words, as film forming methods, the plasma CVD method and the thermal CVD method or the coating method may be employed in combination.

In addition, since in general the plasma CVD film has good film quality, it can be used by itself as the interlayer insulating film under the assumption that it is followed by the planarization such as CMP method, etching-back method, etc. Especially, the high density plasma CVD film is suited for such interlayer insulating film application since it has excellent step coverage. In other words, the interlayer insulating film is formed by virtue of ECR, ICP, high density plasma CVD method such as helicon plasma, etc., and then a surface of the interlayer insulating film is planarized by virtue of CMP (Chemical Mechanical Polishing) method or etching-back method.

Combinations of the above various insulating films which can be used as the interlayer insulating film may be briefed as follows. Illustrative examples which have been used as the interlayer insulating films between four-layered interconnections are shown in FIGS. 1A to 1D.

1) Plasma CVD film+SOG film (FIG. 1A)

2) Plasma CVD film+TEOS/O₃ thermal CVD film (FIG. 1B)

3) Plasma CVD film alone (+CMP) (FIG. 1C)

4) High density plasma CVD film (+CMP) (FIG. 1D) In the case of 3), because the ordinary plasma CVD film is inferior in step coverage, a single plasma CVD film is scarcely used as the interlayer insulating film.

Meanwhile, the above various insulating films which can be used as the interlayer insulating film undergo stress, as indicated in Table II below.

TABLE II

| Type of insulating film | Stress |
|---|---|
| SOG film | tensile stress |
| TEOS/O₃ thermal CVD film | tensile stress |
| Plasma CVD film | compressive stress |
| High density plasma CVD film | compressive stress |

However, no account of stress caused in the overall interlayer insulating film structure has been taken up to this time. As a result, following problems have arisen. That is, in the case of 1) and 2), tensile stress is in general caused in the interlayer insulating film with good step coverage and flatness, i.e., the SOG film or the thermal CVD film (TEOS/O₃ thermal CVD film, etc.). In particular, in the case of thermal CVD film, cracks are generated in the film, as shown in FIG. 2A, if the film thickness is made thick rather than 1.5 μm. For contrast, if the thickness of the insulating film is made excessively thin, interconnection regions cannot be buried completely by the insulating film to thus generate sharp recesses thereon, as shown in FIG. 2B, so that the interconnection conductive film remains in the sharp recesses and flatness of the insulating film is spoiled. Accordingly, there are limitations to employ these insulating films as the single interlayer insulating film. Moreover, it is impossible to employ these insulating films as the interlayer insulating film for the multi-layered interconnections in excess of three layers.

In the case of 3) and 4), extremely large compressive stress is applied as a whole to the insulating films. In order to suppress generation of hillock of the interconnections, etc. and generation of electromigration, it is desired to cover the interconnections with the interlayer insulating film with compressive stress. However, too large compressive stress renders the wafer per se to bend physically, whereby causing problems in manufacturing or problems in device characteristics.

Still further, such a problem has arisen that, if a width of the interconnection is made narrow and a chip size is reduced, stress migration is caused due to stress applied to the interconnection during operation of the device. In other words, if excessively large compressive stress is caused in the insulating film which covers the interconnections such as Al film, etc., the interconnections undergo tensile stress along their grain boundaries to thus lead to breaking of interconnection. The more the layer number of the multi-layered interconnections, the higher the possibility of breaking of interconnection.

### SUMMARY OF THE INVENTION

It is an object of the present invention to provide a stress-adjusted insulating film forming method capable of suppressing electromigration and stress migration in Al interconnections, bowing of wafer, or crack in interlayer insulating film while maintaining step coverage and flatness of the overall interlayer insulating film, a semiconductor device capable of achieving good device characteristics and high reliability, and a method of manufacturing the same.

According to the stress-adjusted insulating film forming method of the present invention, an insulating film having a tensile stress and an insulating film having compressive stress are alternately deposited on a substrate to form the stress-adjusted insulating film consisting of the laminated insulating films.

Therefore, it is possible to adjust the stress of the overall multi-layered insulating films less than a limit stress value (+3×10⁵ dyne/cm which is determined from the experiment) not to generate the cracks in the insulating films, otherwise it is possible to adjust the stress of the overall multi-layered insulating films within the stress range not to cause the curvature of the wafer, degradation in semiconductor device characteristics, etc.

Further, a stress value of the insulating film can be adjusted by adjusting a thickness of the insulating film to be formed, or by adjusting type of film forming gas or film forming conditions (e.g., frequency of plasma generating power, bias power applied to the substrate, heating temperature of the substrate, type of gas, flow rate of gas, etc.). In this case, stress of the overall interlayer insulating films can be calculated with good precision by making use of a calculation equation whose good precision has been confirmed experimentally.

According to the semiconductor device and the method of manufacturing the same of the present invention, the stress-adjusted insulating film (interlayer insulating film) can be formed to cover the interconnection, based on the above stress-adjusted insulating film forming method.

Thereby, generation of crack in the interlayer insulating film, curvature of the wafer caused by stress, degradation in semiconductor device characteristics, etc. can be prevented by adjusting stress of the interlayer insulating film appropriately. In addition to the above, stress migration and electromigration of the interconnection, e.g., the aluminum interconnection, can also be prevented by adjusting stress of the interlayer insulating film appropriately.

Moreover, while preventing generation of cracks in the interlayer insulating film, migration of the interconnections, etc., the interconnections can be laminated as the multi-layered structure via the interlayer insulating film whose stress is adjusted, whereby resulting in the higher integration density of the semiconductor device.

Other and further objects and features of the present invention will become obvious upon an understanding of the illustrative embodiments about to be described in connection with the accompanying drawings or will be indicated in the appended claims, and various advantages not referred to herein will occur to one skilled in the art upon employing of the invention in practice.

### BRIEF DESCRIPTION OF THE DRAWINGS

FIGS. 1A to 1D are sectional views each showing an interlayer insulating film laminated structure in the prior art;

FIGS. 2A and 2B are sectional views showing problems caused in the laminated structure according to the prior art;

FIGS. 3A to 3F are sectional views each showing an interlayer insulating film forming method according to a first embodiment of the present invention;

FIGS. 4A and 4B are characteristic views each showing change in stress due to multilayer stacking of overall interlayer insulating films by virtue of the interlayer insulating film forming method according to the first embodiment of the present invention;

FIGS. 5A and 5B are characteristic views each showing change in stress and generation of crack due to multilayer stacking of overall interlayer insulating films by virtue of the interlayer insulating film forming method according to the first embodiment of the present invention;

FIG. 6 is a characteristic view showing change in stress due to multilayer stacking of overall interlayer insulating films by virtue of the interlayer insulating film forming method according to the first embodiment of the present invention before and after humidity absorption;

FIGS. 7A to 7E are characteristic views each showing stress adjustment depending upon various film forming conditions in a plasma CVD method according to the first embodiment of the present invention;

FIGS. 8A to 8C are characteristic views each showing stress adjustment depending upon various film forming conditions in a thermal CVD method according to the first embodiment of the present invention;

FIGS. 9A to 9C are sectional views each showing an interlayer insulating film laminated structure according to a second embodiment of the present invention;

FIG. 10A is a sectional view showing a semiconductor device and a method of manufacturing the same according to a third embodiment of the present invention; and

FIG. 10B is a characteristic view showing measured values and calculation values in relationships between accumulated laminated thickness and accumulated stress generated in laminated insulating films in FIG. 10A.

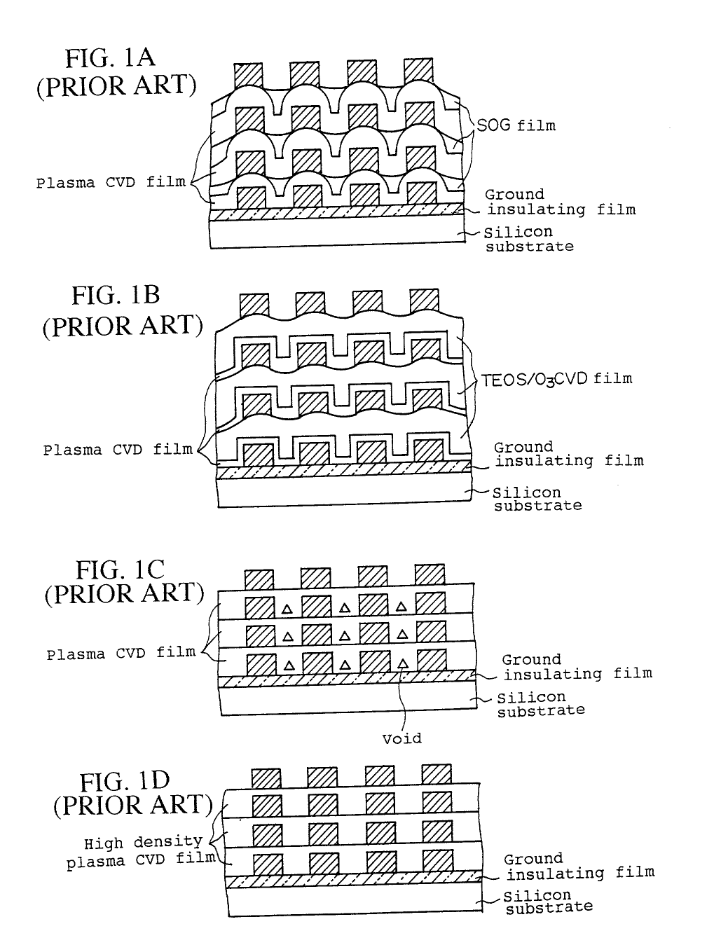

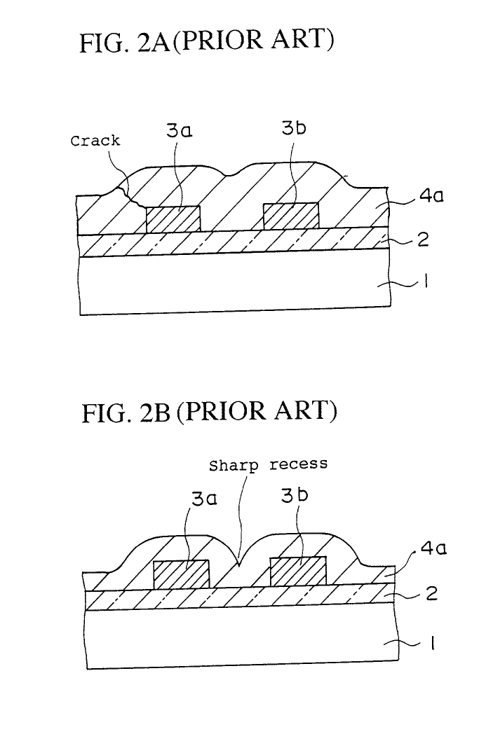

### DESCRIPTION OF THE PREFERRED EMBODIMENTS

Various embodiments of the present invention will be described with reference to the accompanying drawings. It should be noted that the same or similar reference numerals are applied to the same or similar parts and elements throughout the drawings, and the description of the same or similar parts and elements will be omitted or simplified.

(1) First Embodiment

An experiment made to check a stress compensation effect of the present invention will be explained hereunder.

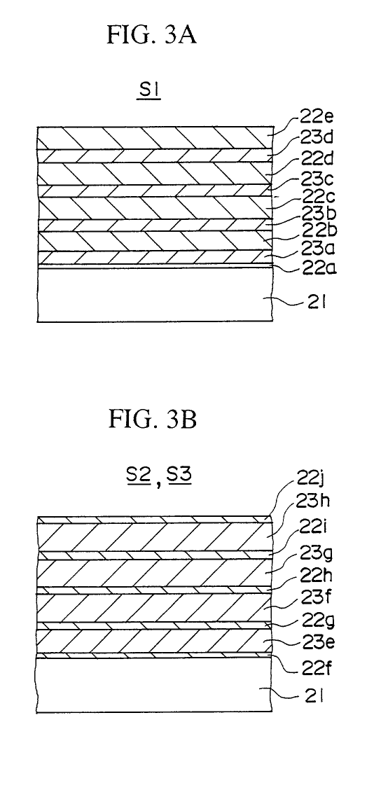

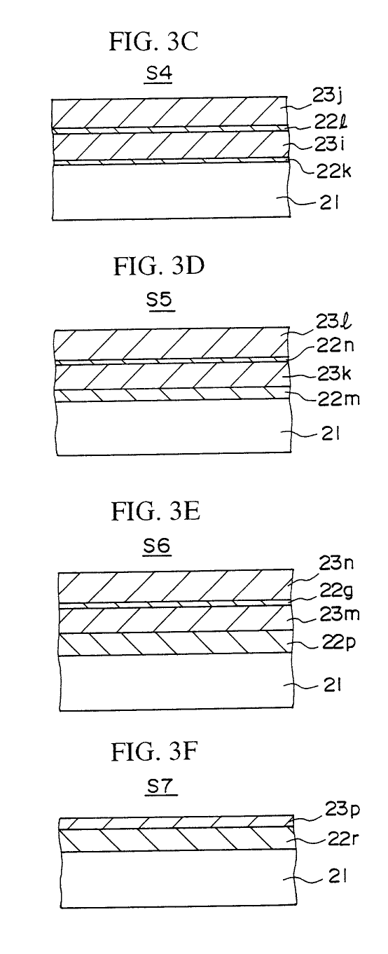

First, a method of forming a sample used in the experiment will be explained. Seven type of samples (S1 to S7) shown in FIGS. 3A to 3F have been used.

(Formation of sample S1)

A laminated structure of the sample S1 is shown in FIG. 3A. Characteristics of respective layers in the sample S1 such as type of insulating film, film thickness, total stress, and generation of crack are indicated in Table III. The insulating film formed by the plasma CVD method will be called a PECVD film (plasma CVD film) hereinafter, and the insulating film formed by the thermal CVD method will be called a THCVD film (thermal CVD film) hereinafter. Further, “total stress” indicated in Table III means stress generated in the overall insulating films after respective insulating films have been laminated, which is calculated according to an amount of bowing generated after respective insulating films have been laminated on a silicon wafer. A calculation method is effected based on a literature, i.e., J. Vac. Scl. Technol. A, Vol.14, No.3, May/June 1986, pp.645-649. Similarly, in Tables IV to IX, total stresses have also been calculated according to the same calculation method.

TABLE III

| | Type of | Film | Total | |
|---|---|---|---|---|
| Layer | insulating | thickness | stress | Crack |
| (numeral) | film | (μm) | (× 10⁵ dyne/cm) | generation |
| 1st layer (22a) | PECVD film | 0.2 | −0.38 | none |
| 2nd layer (23a) | THCVD film | 0.5 | +0.53 | none |
| 3rd layer (22b) | PECVD film | 1.0 | −2.0 | none |
| 4th layer (23b) | THCVD film | 1.45 | −1.4 | none |
| 5th layer (22c) | PECVD film | 0.4 | −5.4 | none |
| 6th layer (23c) | THCVD film | 1.45 | −4.5 | none |
| 7th layer (22d) | PECVD film | 0.4 | −9.0 | none |
| 8th layer (23d) | THCVD film | 1.45 | −8.3 | none |
| 9th layer (22e) | PECVD film | 0.4 | ≦−10.7 | none |

In the above Table III, film forming conditions for the plasma CVD film except for a film forming time are common throughout all laminated layers, and they are set forth hereunder.

| | |
|---|---|
| Film forming gas | TMS (15 sccm) + N₂O (450 sccm) |
| (Flow rate sccm) | |

| | | |
|---|---|---|
| Pressure | 0.7 | Torr |
| Plasma generating power | 150 | W |
| Frequency | 13.56 | MHz |
| Bias power | 150 | W |
| Frequency | 330 | kHz |
| Substrate temperature | 330° | C. |
| (Film forming temperature) | | |
| Film forming rate | 150 | nm/min |

Under the film forming conditions defined as above, a silicon oxide film having compressive stress of −3.3×10⁹ dyne/cm² can be formed.

Moreover, film forming conditions of the thermal CVD film except for a film forming time are common in respective layers, which are set forth hereunder.

| | |
|---|---|
| Film forming gas | TEOS (1500 sccm) + |
| (Flow rate sccm) | O₃ 5% in O₂ 7.5 l) |

| | | |
|---|---|---|
| Substrate temperature | 400° | C. |
| (Film forming temperature) | | |
| Film forming rate | 87 | nm/min |

Under the film forming conditions defined as above, a silicon oxide film having tensile stress of +2.2×10⁹ dyne/cm² can be formed.

As the organic silane to be included in the film forming gas, TMS (trimethoxysilane: HSi(OCH₃)₃) or TEOS(tetraethylorthosilicate: Si(OC₂H₅)₄) has been employed in the plasma CVD method and the thermal CVD method. However, such organic silane may be formed of any of alkylsilane or allylsilane (general formula: RₙSiH₄₋ₙ (n=1 to 4)), alkoxysilane (general formula: (RO)ₙSiH₄₋ₙ (n=1 to 4)), chain siloxane (general formula: RₙH₃₋ₙSiO(RₖH₂₋ₖSiO)ₘSiH₃₋ₙRₙ (n=1 to 3; k=0 to 2; m≧0)), derivative of chain siloxane (general formula: (RO)ₙH₃₋ₙSiOSiH₃₋ₙ(OR)ₙ (n=1 to 3)), and ring siloxane (general formula: (RₖH₂₋ₖSiO)ₘ (k=1, 2; m≧2)) (where R is alkyl group, allyl group, or their derivative).

Still further, ozone (O₃ or oxygen (O₂) has been employed as the oxygen containing gas. However, the oxygen containing gas may be formed of any of N₂O, NO₂, CO, CO₂, and H₂O.

(Formation of sample S2)

A laminated structure of the sample S2 is shown in FIG. 3B. Type of insulating film, film thickness, total stress, and generation of crack in respective layers of the sample S2 are indicated in Table IV.

TABLE IV

| | Type of | Film | Total | |
|---|---|---|---|---|
| Layer | insulating | thickness | stress | Crack |
| (numeral) | film | (μm) | (× 10⁵ dyne/cm) | generation |
| 1st layer (22f) | PECVD film | 0.2 | −0.58 | none |
| 2nd layer (23e) | THCVD film | 1.2 | +2.0 | none |
| 3rd layer (22g) | PECVD film | 0.3 | +0.92 | none |
| 4th layer (23f) | THCVD film | 1.5 | +4.0 | none |
| 5th layer (22h) | PECVD film | 0.35 | +2.4 | none |
| 6th layer (23g) | THCVD film | 1.5 | +5.8 | none |
| 7th layer (22i) | PECVD film | 0.35 | +4.0 | generated |
| 8th layer (23h) | THCVD film | 1.5 | +6.7 | remaining |
| 9th layer (22j) | PECVD film | 0.25 | +4.7 | remaining |

In the above Table IV, film forming conditions of the plasma CVD film other than a film forming time are common throughout all laminated layers, and they are set identically to the case where the sample S1 is formed.

Also, film forming conditions of the thermal CVD film other than a film forming time are common in respective layers, and they are set identically to the case where the sample S1 is formed.

(Formation of sample S3)

A laminated structure of the sample S3 is also shown in FIG. 3B. Type of insulating film, film thickness, total stress, and generation of crack in respective layers of the sample S3 are indicated in Table V.

TABLE V

| | Type of | Film | Total | |
|---|---|---|---|---|
| Layer | insulating | thickness | stress | Crack |
| (numeral) | film | (μm) | (× 10⁵ dyne/cm) | generation |
| 1st layer (22f) | PECVD film | 0.2 | −0.69 | none |
| 2nd layer (23e) | THCVD film | 1.2 | +2.3 | none |
| 3rd layer (22g) | PECVD film | 0.4 | +0.6 | none |
| 4th layer (23f) | THCVD film | 1.45 | +3.7 | none |
| 5th layer (22h) | PECVD film | 0.4 | +1.5 | none |
| 6th layer (23g) | THCVD film | 1.45 | +5.1 | none |
| 7th layer (22i) | PECVD film | 0.4 | +2.6 | none |
| 8th layer (23h) | THCVD film | 1.45 | +5.3 | none |
| 9th layer (22j) | PECVD film | 0.2 | +3.4 | none |

In the above Table V, film forming conditions of the plasma CVD film except for a film forming time are common throughout all laminated layers, and they are identical to the case where the sample S1 is formed.

Further, film forming conditions of the thermal CVD film except for a film forming time are common in respective layers, and they are identical to the case where the sample S1 is formed.

(Formation of sample S4)

A laminated structure of the sample S4 is shown in FIG. 3C. Type of insulating film, film thickness, total stress, and generation of crack in respective layers of the sample S4 are indicated in Table VI.

TABLE VI

| | Type of | Film | Total | |
|---|---|---|---|---|
| Layer | insulating | thickness | stress | Crack |
| (numeral) | film | (μm) | (× 10⁵ dyne/cm) | generation |
| 1st layer (22k) | PECVD film | 0.1 | −0.34 | none |
| 2nd layer (23i) | THCVD film | 1.5 | +3.4 | none |
| 3rd layer (22l) | PECVD film | 0.1 | — | none |
| 4th layer (23j) | THCVD film | 1.6 | +6.8 | generated |

In the above Table VI, film forming conditions of the plasma CVD film other than a film forming time are common throughout all laminated layers, which are identical to the case where the sample S1 is formed.

In addition, film forming conditions of the thermal CVD film other than a film forming time are common in respective layers, which are identical to the case where the sample S1 is formed.

(Formation of sample S5)

A laminated structure of the sample S5 is shown in FIG. 3D. Type of insulating film, film thickness, total stress, and generation of crack in respective layers of the sample S5 are indicated in Table VII.

TABLE VII

| | Type of | Film | Total | |
|---|---|---|---|---|
| Layer | insulating | thickness | stress | Crack |
| (numeral) | film | (μm) | (× 10⁵ dyne/cm) | generation |
| 1st layer (22m) | PECVD film | 0.1 | −0.34 | none |
| 2nd layer (23k) | THCVD film | 1.5 | +3.4 | none |
| 3rd layer (22n) | PECVD film | 0.1 | — | none |
| 4th layer (23l) | THCVD film | 1.6 | +6.8 | none |

In the above Table VII, film forming conditions of the plasma CVD film other than a film forming time are common throughout all laminated layers, which are set to be identical to the case where the sample S1 is formed.

In addition, film forming conditions of the thermal CVD film other than a film forming time are common in respective layers, which are set to be identical to the case where the sample S1 is formed.

(Formation of sample S6)

A laminated structure of the sample S6 is shown in FIG. 3E. Type of insulating film, film thickness, total stress, and generation of crack in respective layers of the sample S6 are indicated in Table VIII.

TABLE VIII

| | Type of | Film | Total | |
|---|---|---|---|---|
| Layer | insulating | thickness | stress | Crack |
| (numeral) | film | (μm) | (× 10⁵ dyne/cm) | generation |
| 1st layer (22p) | PECVD film | 1.1 | −3.2 | none |
| 2nd layer (23m) | THCVD film | 1.2 | −0.65 | none |
| 3rd layer (22q) | PECVD film | 0.1 | — | none |
| 4th layer (23n) | THCVD film | 1.7 | +2.7 | none |

In the above Table VIII, film forming conditions of the plasma CVD film other than a film forming time are common in respective layers, and they are set identically to the case where the sample S1 is formed.

In addition, film forming conditions of the thermal CVD film other than a film forming time are common in respective layers and they are set identically to the case where the sample S1 is formed.

(Formation of sample S7)

A laminated structure of the sample S7 is shown in FIG. 3F. Type of insulating film, film thickness, total stress, and generation of crack in respective layers of the sample S7 are indicated in Table IX.

TABLE IX

| | Type of | Film | Total | |
|---|---|---|---|---|
| Layer | insulating | thickness | stress | Crack |
| (numeral) | film | (μm) | ( × 10⁵ dyne/cm) | generation |
| 1st layer (22r) | PECVD film | 1.3 | 3.9 | none |
| 2nd layer (23p) | THCVD film | 0.5 | -0.17 | none |

In the above Table IX, film forming conditions of the plasma CVD film other than a film forming time are common throughout all laminated layers, which are identical to the case where the sample S1 is formed.

In addition, film forming conditions of the thermal CVD film other than a film forming time are common in respective layers, which are identical to the case where the sample S1 is formed.

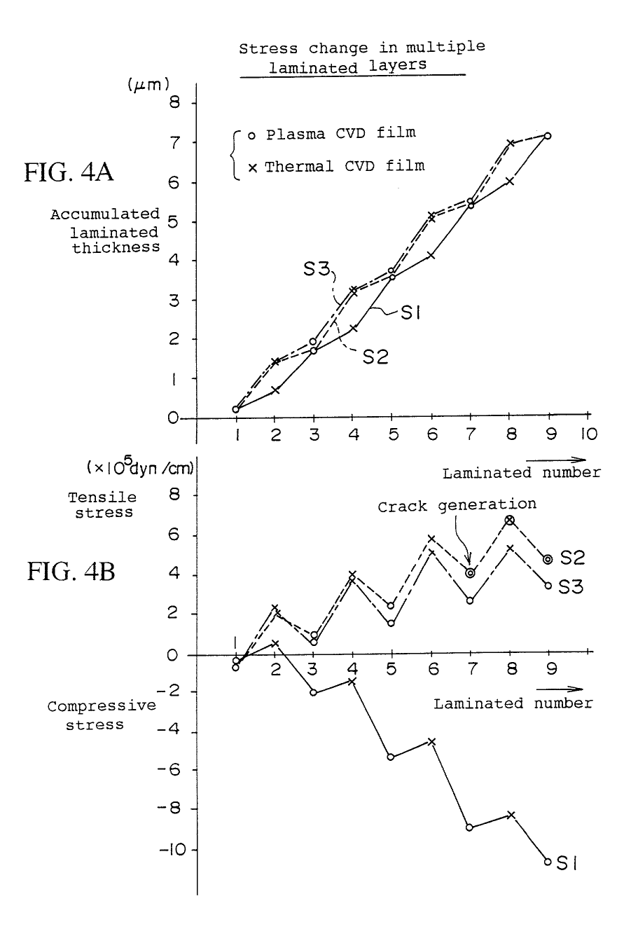

Subsequently, the results are shown in FIGS. 4A and 4B when change in stress is summarized in the samples S1 to S3 respectively based on stress values indicated in above Tables III to V after respective insulating layers have been laminated.

FIG. 4A is a view showing accumulated laminated film thicknesses, wherein an ordinate shows the accumulated laminated film thickness on a linear scale and an abscissa shows the number of laminated layer. FIG. 4B is a characteristic view showing change in stress after respective insulating films are laminated, wherein an ordinate shows the stress value (×10⁵ dyne/cm) on a linear scale and an abscissa shows the number of laminated layer.

As shown in FIGS. 4A and 4B, it is feasible to adjust stress of the overall interlayer insulating films by adjusting respective film thicknesses of the PECVD film and the THCVD film. If the thicknesses of the PECVD films are set large rather than the THCVD films like the sample S1, compressive stress has become dominant as a whole. On the contrary, if the THCVD films are made thicker than the PECVD films like the samples S2 and S3, tensile stress has become dominant as a whole. In the case of the samples S1, S3, even through the film thickness exceeds 7 μm, no crack has been generated by adjusting stress of overall interlayer insulating films appropriately.

In the sample S2, cracks are generated when the seventh layer PECVD film 22i is formed continuously after the sixth layer THCVD film 23g has been laminated. The cracks are generated in all laminated insulating films. The experiment suggests evidently that, if tensile stress exceeds a certain threshold stress value, the cracks would be generated. From the experiment, it may be deduced that the threshold stress value not to generate the cracks is 4 to 6×10⁵ dyne/cm. In the sample S2, the reason why no crack has been generated even though stress has already exceeded 5.8×10⁵ dyne/cm immediately after lamination of the sixth insulating layer but the cracks have been generated even though stress has already reduced after lamination of the seventh insulating layer may be considered as follows. That is, no crack barely appears in the sixth layer THCVD film 23g since stress in the sixth layer THCVD film 23g has been relaxed to some extent because of its humidity absorption, nevertheless stress may be increased locally in the THCVD film 23g due to dehydration of the THCVD film 23g since the THCVD film 23g is exposed to plasma irradiation during forming the seventh layer PECVD film 22i.

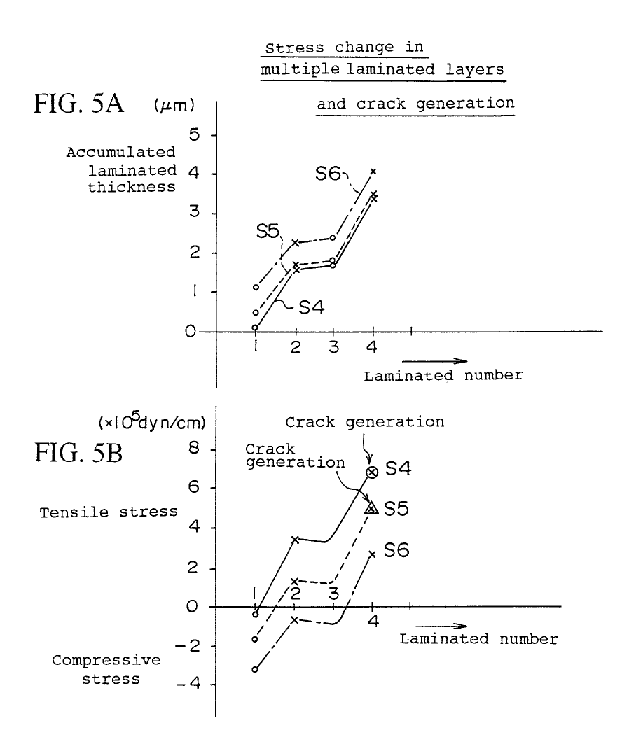

In turn, the results are shown in FIGS. 5A and 5B when change in stress is summarized in the samples S4 to S6 respectively based on the stress values indicated in above Tables VI to VIII after the multiple insulating layers have been laminated.

FIG. 5A is a view showing accumulated laminated film thicknesses, wherein an ordinate shows the accumulated laminated film thickness (μm) on a linear scale and an abscissa shows the number of laminated layer. FIG. 5B is a characteristic view showing change in stress after respective insulating films are laminated, wherein an ordinate shows the stress value (×10⁵ dyne/cm) on a linear scale and an abscissa shows the number of laminated layer.

As shown in FIGS. 5A and 5B, three samples S4 to S6 are directed to the case where the THCVD films are made thicker than the PECVD films. The cracks appear in the samples S4 and S5, nevertheless no crack appears in the sample S6. In this case, like FIGS. 4A and 4B, it may be deduced that the threshold stress value not to generate the cracks is 4 to 6×10⁵ dyne/cm. From another experiment, it has been deduced that a stress range not to generate the cracks is less than +2×10⁵ dyne/cm if the insulating film is formed on the Al film.

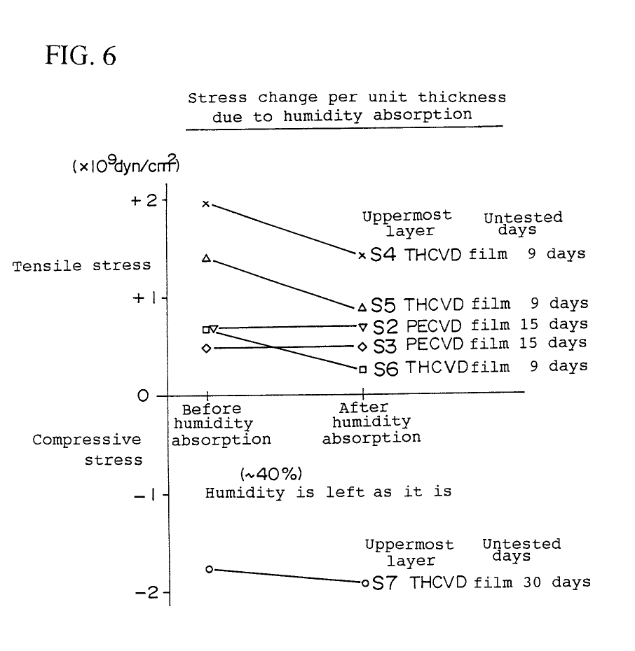

In addition, the results are shown in FIG. 6 when change in stress is investigated in the samples S2 to S7 respectively before and after humidity absorption after the multiple insulating layers are laminated.

FIG. 6 is a characteristic view showing change in stress before and after humidity absorption, wherein an ordinate shows the average stress value (×10⁹ dyne/cm²) caused in the laminated films on a linear scale and an abscissa shows the time interval before and after humidity absorption. In the above experiment, it seems that ambient humidity of the sample has been about 40% and that humidity absorption has occurred mainly in the thermal CVD films of all the laminated films.

As shown in FIG. 6, it would be evident that variation in stress due to humidity absorption has been large in the samples S4 to S7, in which the uppermost layer is formed of the THCVD film, compared to the samples S2, S3, in which the uppermost layer is formed of the PECVD film. The stress has been shifted towards the compressive stress side due to humidity absorption in the samples S4 to S7. It is desired that the uppermost layer should be formed of the PECVD film if suppression of variation in stress is needed. Otherwise, from another experiment, it has been confirmed that plasma irradiation after film formation is effective to suppress variation in stress.

It has been found from the above experimental results that stress caused in the overall laminated films can be calculated according to the following equation. That is,

Stress in overall laminated films

$$( {σ}_{T} ) = {\sum }_{i = 1}^{n} ( {t}_{i} \times {σ}_{i} )$$

Where n is the total laminated number, ti is a thickness of i-th insulating film (cm), and σᵢ is stress in i-th insulating film (dyne/cm²). As for type of stress of the insulating film, it is assumed that the tensile stress is positive and the compressive stress is negative.

It has been confirmed that, under the assumption that a stress value σ of the plasma CVD film is −3×10⁹ dyne/cm2 and a stress value σ of the thermal CVD film is +2×10⁹ dyne/cm², stress values calculated according to the above equation exactly coincide with measured stress values, as indicated in Tables III to IX.

From the samples S2, S4, S5, it is understood that a stress range not to generate the cracks is less than about +3×10⁵ dyne/cm. If stress of the silicon oxide film formed by the thermal CVD method is assumed as 2×10⁹ dyne/cm, this corresponds to about 1.5 μm in terms of the thickness of the silicon oxide film formed by the thermal CVD method.

Therefore, if stress of the overall laminated films calculated by the equation is set to a stress limit (+3×10⁵ dyne/cm on an Si film, or +2×10⁵ dyne/cm on an aluminum film) and then thickness and stress of individual insulating films are determined not to exceed this stress limit, cracks in the interlayer insulating films can be prevented.

Depending upon the film forming method and the film forming conditions, stress in the insulating film formed by the plasma CVD method and stress in the insulating film formed by the thermal CVD method can be adjusted as explained hereunder.

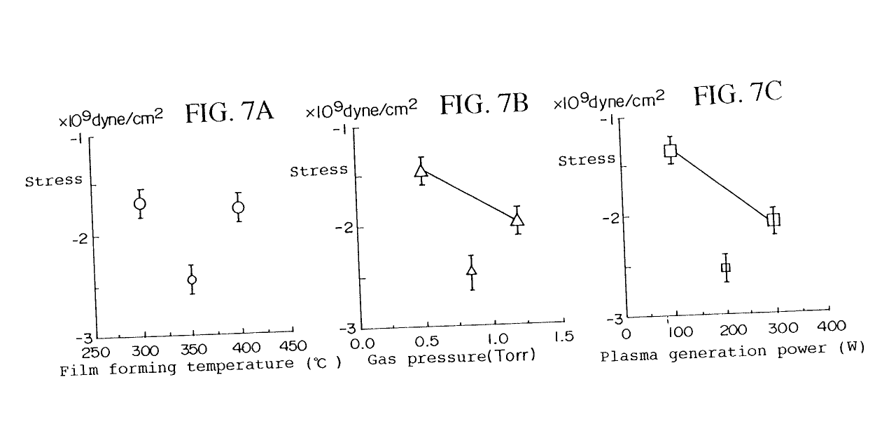

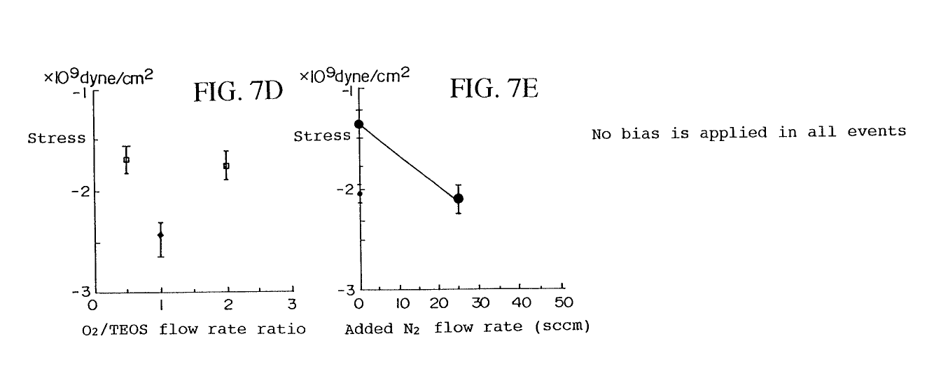

For instance, stress in the insulating film formed by the plasma CVD method can be adjusted according to type of gas, flow rate of gas, frequency of plasma generating power, bias power applied to the substrate, film forming temperature, etc. Experimental examples are shown in FIGS. 7A to 7E. Although TEOS+O₂ system reaction gas has been employed in the experimental examples, stress may be adjusted in a similar manner when TMS+N₂O system reaction gas is employed.

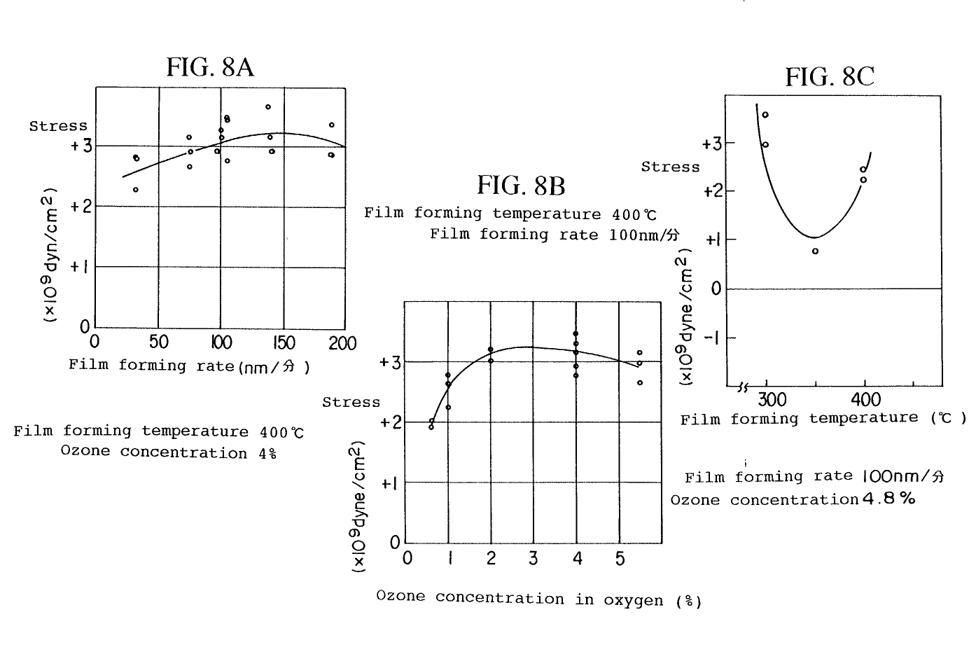

Also stress in the insulating film formed by the thermal CVD method can be adjusted according to type of gas, flow rate of gas (including ozone concentration in oxygen), film forming temperature, film forming rate, etc. Experimental examples are shown in FIGS. 8A to 8C. The TEOS+O₃ reaction gas has been employed as the film forming gas.

Usually, stress in the insulating film formed by the thermal CVD method is often shifted to the compressive stress side because of humidity absorption after formation. Therefore, if moisture is removed from the insulating film by virtue of plasma irradiation, stress in the insulating film can be shifted to the tensile stress side. As a result, it is possible to stabilize stress in the insulating film.

(2) Second Embodiment

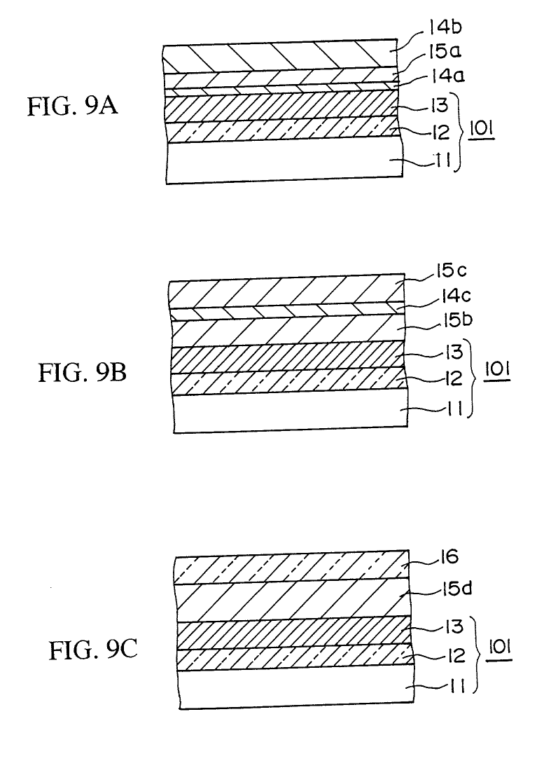

FIGS. 9A to 9C are sectional views showing combinations of the insulating films constituting interlayer insulating films according to a second embodiment of the present invention.

FIG. 9A shows a structure wherein insulating films 14a, 14b and an insulating film 15a are laminated alternatively on a substrate 101 by the plasma CVD method and the thermal CVD method respectively. The substrate 101 consists of a ground insulating film 12 formed on a semiconductor substrate 11 and an interconnection layer 13 formed on the ground insulating film 12.

In the above structure, since thicknesses of the PECVD films 14a, 14b are large, compressive stress becomes dominant in stress in the overall laminated films when stress in the overall laminated films is calculated according to the above equation. Thus, generation of the cracks can be prevented. In the event that it is expected not to excessively increase an absolute value of compressive stress, a lower limit of stress (lower limit of the compressive stress) in the overall laminated films according to the equation as well as an upper limit thereof (upper limit of the tensile stress to suppress generation of the cracks) is defined, and then thicknesses and stress of the PECVD films 14a, 14b and the THCVD film 15a must be selected so that the stress is laid within the range between the upper limit and the lower limit.

FIG. 9B shows a structure wherein insulating films 15b, 15c by the thermal CVD method and an insulating film 14c by the plasma CVD method are laminated alternatively on the substrate 101 in a reverse order to that in FIG. 9A.

In the above structure, since thicknesses of the THCVD films 15b, 15c are large, tensile stress becomes dominant in stress in the overall laminated films when stress in the overall laminated films is calculated according to the above equation. The thicknesses and stress of the PECVD film 14c and the THCVD films 15b, 15c may be selected so as to adjust stress in the overall laminated films according to the equation below the upper limit of the tensile stress beyond which the cracks generate. Consequently, generation of the cracks can be prevented.

FIG. 9C shows a structure wherein impurity non-containing silicon oxide film (NSG film) 15d and an impurity containing insulating film 16 which includes at least one of phosphorus and boron are laminated alternatively on the substrate 101 by the thermal CVD method. PSG film, BPSG film, or BSG film used as the impurity containing insulating film 16 has tensile stress of about +5×10⁸ dyne/cm².

Calculation according to the equation provides tensile stress as stress in the overall laminated films. However, such tensile stress can be reduced by inserting the impurity containing insulating film 16 in contrast to the case where only the impurity non-containing silicon oxide films (NSG film) 15d are laminated. Therefore, in case the thickness of the interlayer insulating film is desired to be made thick especially, such thickness can be made larger by inserting the impurity containing insulating film 16 appropriately into the interlayer insulating films in contrast to the case where the interlayer insulating film is formed of the NSG film only.

In the above structure, although the interlayer insulating film has been constituted by the insulating films of a three-layered structure, the insulating films of two-layered structure or four-layered structure or more may be adopted. In addition, although the one-layered interconnection has been employed, plural-layered interconnections can be laminated and then the above interlayer insulating films can be interposed between the interconnections.

(3) Third Embodiment

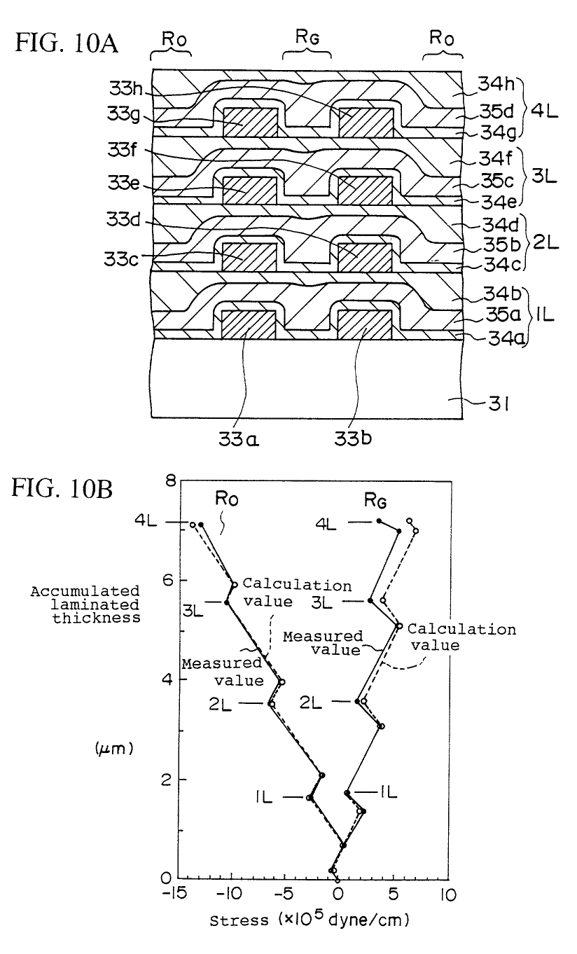

A semiconductor device and a method of manufacturing the same according to a third embodiment of the present invention will be explained with reference to FIG. 10A hereinbelow. FIG. 10A shows an example in which a four-layered interconnections are formed. The interlayer insulating films formed according to the method of manufacturing the interlayer insulating film of the present invention are interposed respectively between neighboring two interconnections of the four layered interconnections. Film forming gas and film forming conditions used in the plasma CVD method and the thermal CVD method are selected identically to those explained in forming the sample S1 in the first embodiment.

As shown in FIG. 10A, interconnections 33a, 33b made of an aluminum film having a thickness of 0.7 μm are formed on a substrate 31.

First, a silicon oxide film 34a of 0.2 μm thickness is formed by virtue of the plasma CVD method to cover the interconnections 33a, 33b.

Then, a silicon oxide film 35a of 0.5 μm thickness is formed on the silicon oxide film 34a by virtue of the thermal CVD method.

In turn, a silicon oxide film 34b of 0.9 μm thickness is formed on the silicon oxide film 35a by virtue of the plasma CVD method.

Subsequently, a surface of the silicon oxide film 34b is planarized by polishing the silicon oxide film 34b by virtue of CMP method (Chemical Mechanical Polishing Method). Thereby, formation of the first-layered interlayer insulating film 1L having a thickness of 1.6 μm to cover the first-layered interconnections 33a, 33b is completed.

Next, second-layered interconnections 33c, 33d made of an aluminum film having a thickness of 0.95 μm are formed on the planarized silicon oxide film 34b.

Then, a second-layered interlayer insulating film 2L having a thickness of 1.85 μm is formed by repeating the above steps. The second-layered interlayer insulating film 2L consists of a silicon oxide film 34c of 0.1 μm thickness formed by the plasma CVD method, a silicon oxide film 35b of 0.45 μm thickness formed by the thermal CVD method, and a silicon oxide film 34d of 1.3 μm thickness formed by the plasma CVD method.

Then, third-layered interconnections 33e, 33f made of an aluminum film having a thickness of 0.95 μm and a third-layered interlayer insulating film 3L having a thickness of 1.85 μm are formed in this order on the second-layered interlayer insulating film 2L. The third-layered interlayer insulating film 3L consists of a silicon oxide film 34e of 0.1 μm thickness formed by the plasma CVD method, a silicon oxide film 35c of 0.45 μm thickness formed by the thermal CVD method, and a silicon oxide film 34f of 1.3 μm thickness formed by the plasma CVD method.

Then, fourth-layered interconnections 33g, 33h made of an aluminum film having a thickness of 0.95 μm and a fourth-layered covering insulating film 4L having a thickness of 1.85 μm are formed in this order on the third-layered interlayer insulating film 3L. The covering insulating film 4L consists of a silicon oxide film 34g of 0.1 μm thickness formed by the plasma CVD method, a silicon oxide film 35d of 0.45 μm thickness formed by the thermal CVD method, and a silicon oxide film 34h of 1.3 μm thickness formed by the plasma CVD method.

With the above, four layered interconnections, three interlayer insulating films 1L to 3L which are interposed respectively between neighboring two interconnections of the four interconnections, and the covering insulating film 4L for covering the fourth layer interconnection have been formed. The preselected interconnections of the interconnections are connected through via holes (not shown) formed in the interlayer insulating films 1L to 3L, into which conductive layers are buried.

Change in accumulated stress of the semiconductor device formed as above is shown in FIG. 10B.

FIG. 10B is a characteristic view showing measured values and calculation values in relationships between accumulated laminated thickness and accumulated stress generated in laminated insulating films in FIG. 10A. In FIG. 10B, an ordinate shows an accumulated laminated thickness (μm) on a linear scale and an abscissa shows a stress value (×10⁵ dyne/cm)) on a linear scale. The reason why measuring points do not coincide with the layer number is that the adjacent silicon oxide films 34b and 34c, 34d and 34e, 34f and 34g which are formed by the plasma CVD method are regarded as one point respectively.

According to the results shown in FIG. 10B, in the multilayered structure formed similarly as the actual semiconductor device, the measured values substantially coincide with the calculated values in relationships between accumulated laminated thickness and accumulated stress in the insulating films. The reason why no crack appears in the insulating film even when accumulated stress has exceeded the stress limit 3×10⁵ dyne/cm defined in the first embodiment are put forth hereunder. That is, this is because the actual stress limit is considerably high rather than 3×10⁵ dyne/cm but the stress limit is reduced smaller if abnormal defects are caused in the insulating film, nevertheless the stress limit should be selected not to generate the cracks in such abnormal case.

According to the above, if stress of the overall laminated interlayer insulating films, etc. 1L to 4L is set not to exceed the stress limit (3×10⁵ dyne/cm on the insulating film, 2×10⁵ dyne/cm on the aluminum film), the arbitrary number of interconnections can be laminated without generating the crack in respective interlayer insulating films.

If the above stress limits are restricted narrower, generation of the crack can be suppressed much more, and the curvature of the wafer, degradation in the semiconductor device characteristics, etc. due to stress can also be prevented, and further stress migration or electromigration of the interconnection, e.g., aluminum interconnection, can be prevented.

In addition, if multilayered interconnections are laminated via the stress-adjusted interlayer insulating films while preventing generation of the crack in the interlayer insulating film, etc. and electromigration of the interconnection, etc., the semiconductor device having the high integration density can be accomplished.

Stress in the insulating film formed on the interconnections 33a to 33h has not been measured or calculated in the above disclosure. Since, as described above, the thickness and the stress limits of the insulating film are different on the interconnections 33a to 33h and on regions in which the interconnections 33a to 33h are not formed, stress in respective regions must be calculated individually to correspond to the thickness according to the equation derived in the first embodiment, and then the thickness must be determined to suppress the stress in respective regions within the preselected stress range.

As described earlier, according to the interlayer insulating film forming method of the present invention, multiple insulating layers whose total stress is adjusted can be formed by laminating insulating films having different stress mixedly on the substrate.

Accordingly, it is possible to adjust the stress of the overall multilayered insulating films less than the limit stress value not to generate the cracks in the insulating film, otherwise it is possible to adjust the stress of the overall multilayered insulating films within the stress range not to cause the curvature of the wafer, degradation in the semiconductor device characteristics, etc. due to stress.

Further, a stress value of the insulating film can be adjusted by adjusting the thickness of the insulating film to be formed, or by adjusting type of film forming gas or film forming conditions. In this case, stress of the overall interlayer insulating films can be calculated with good precision by making use of a calculation equation whose good precision has been confirmed experimentally.

According to the semiconductor device and the method of manufacturing the same of the present invention, the interlayer insulating film whose stress is adjusted can be formed to cover the interconnection, based on the above interlayer insulating film forming method.

Consequently, generation of crack in the interlayer insulating film, curvature of the wafer because of stress., degradation in semiconductor device characteristics, etc. can be prevented by adjusting stress of the interlayer insulating film appropriately. In addition to the above, stress migration and electromigration of the interconnection, e.g., the aluminum interconnection, can also be prevented by adjusting stress of the interlayer insulating film appropriately. Moreover, while preventing generation of cracks in the interlayer insulating films, migration of the interconnections, etc., the interconnections can be laminated as the multilayered structure via the interlayer insulating films whose stress is adjusted, whereby resulting in the higher integration density of the semiconductor device.

Various modifications will become possible for those skilled in the art after receiving the teachings of the present disclosure without departing from the scope thereof.

What is claimed is:

1. A stress-adjusted insulating film forming method being characterized in that an insulating film having a tensile stress and an insulating film having compressive stress are alternately deposited on a substrate to form said stress-adjusted insulating film consisting of said laminated insulating films.

2. A stress-adjusted insulating film forming method according to claim 1, wherein stress in said overall stress-adjusted insulating film is adjusted according to
Stress in overall stress-adjusted insulating film
$$( {σ}_{T} ) = {\sum }_{i = 1}^{n} ( {t}_{i} \times {σ}_{i} )$$
(Where tᵢ is a thickness of the i-th insulating film of said stress-adjusted insulating film, and σᵢ is stress in the i-th insulating film of said stress-adjusted insulating film (tensile stress is positive while compressive stress is negative).)

3. A stress-adjusted insulating film forming method according to claim 2, wherein said stress in overall stress-adjusted insulating film (σ_{T}) is tensile stress or compressive stress of less than +3×10⁵ dyne/cm.

4. A stress-adjusted insulating film forming method according to claim 1, wherein said insulating film is a silicon oxide film or a silicon containing insulating film including at least any of phosphorus and boron.

5. A stress-adjusted insulating film forming method according to claim 1, wherein said insulating film having tensile stress is deposited by reacting a gas mixture including organic silane and oxygen containing gas by virtue of heating.

6. A stress-adjusted insulating film forming method according to any of claim 5, wherein said gas mixture further includes impurity containing gas.

7. A stress-adjusted insulating film forming method according to claim 5, wherein said insulating film having tensile stress is subjected to plasma irradiation after said insulating film having tensile stress is formed.

8. A stress-adjusted insulating film forming method according to claim 5, wherein said organic silane is one selected from the group consisting of alkylsilane or allylsilane (general formula: RₙSiH₄₋ₙ (n=1 to 4)), alkoxysilane (general formula: (RO)ₙSiH₄₋ₙ (n=1 to 4)), chain siloxane (general formula: RₙH₃₋ₙSi)(RₖH₂₋ₗSiO)ₘSH₃₋ₙRₙ (n=1 to 3; k=0 to 2; m≧0)), derivative of chain siloxane (general formula: (RO)ₙH₃₋ₙSiOSiH₃₋ₙ(OR)ₙ (n=1 to 3)), and ring siloxane (general formula: (RₖH₂₋ₖSiO)ₘ (k=1, 2; m≧2)) (where R is alkyl group, allyl group, or their derivative).

9. A stress-adjusted insulating film forming method according to claim 5, wherein said oxygen containing gas is one selected from the group consisting of ozone (O₃), oxygen (O₂), N₂O, NO₂, CO, CO₂, and H₂O.

10. A stress-adjusted insulating film forming method according to claim 5, wherein said film forming condition of respective insulating films to adjust stress characteristics of respective insulating films is at least one selected from the group consisting of a film forming temperature, type of gas, and a flow rate of gas.

11. A stress-adjusted insulating film forming method according to claim 1, wherein said insulating film having compressive stress is deposited by reacting a gas mixture including organic silane and oxygen containing gas by virtue of plasmanization.

12. A stress-adjusted insulating film forming method according to claim 11, wherein said organic silane is one selected from the group consisting of alkylsilane or allylsilane (general formula: RₙSiH₄n (n=1 to 4)), alkoxysilane (general formula: (RO)ₙSiH₄₋ₙ (n=1 to 4)), chain siloxane (general formula: RₙH₃₋ₙSiO(RₖH₂₋ₖSiO)ₘSiH₃₋ₙRₙ (n=1 to 3; k=0 to 2; m≧0)), derivative of chain siloxane (general formula: (RO)ₙH₃₋ₙSiOSiH₃₋ₙ(OR)ₙ (n=1 to 3)), and ring siloxane (general formula: (RₖH₂₋ₖSiO)ₘ (k=1, 2; m≧2)) (where R is alkyl group, allyl group, or their derivative).

13. A stress-adjusted insulating film forming method according to claim 11, wherein said oxygen containing gas is one selected from the group consisting of ozone (O₃), oxygen (O₂), N₂O, NO₂, CO, CO₂, and H₂O,

14. A stress-adjusted insulating film forming method according to claim 11, wherein said film forming condition of respective insulating films to adjust stress characteristics of respective insulating films is at least one selected from the group consisting of a frequency of plasma generating power, a bias power applied to said substrate, a film forming temperature, type of gas, and a flow rate of gas.

15. A semiconductor device manufacturing method being characterized in that an insulating film having a tensile stress and an insulating film having compressive stress are alternately deposited covering an interconnection layer on a substrate to form a stress-adjusted insulating film.

16. A semiconductor device manufacturing method according to claim 15, wherein material of said interconnection layer is aluminum.

17. A semiconductor device manufactured according to a semiconductor device manufacturing method set forth in claim 15.

18. A semiconductor device manufacturing method comprising the steps of:
(a) forming an interconnection layer on a substrate;
(b) forming a stress-adjusted insulating film in which an insulating film having a tensile stress and an insulating film having compressive stress are alternately laminated covering said interconnection layer on said substrate;
(c) repeating said steps of (a) and (b) to laminate altrnately interconnection layers and stress-adjusted insulating films.

19. A semiconductor device manufacturing method according to claim 18, wherein material of said interconnection layer is aluminum.

20. A semiconductor device manufactured according to a semiconductor device manufacturing method set forth in claim 18.
